(19) United States
(12) Patent Application Publication
(10) Pub. No.: US 2010/0080032 A1
(43) Pub. Date: Apr. 1, 2010

(54) SEMICONDUCTOR DEVICE

(75) Inventor: KAZUHIRO NOJIMA, TOKYO (JP)

Correspondence Address: YOUNG & THOMPSON, 209 Madison Street, Suite 500, Alexandria, VA, 22314, US

(73) Assignee: ELPIDA MEMORY, INC., TOKYO (JP)

(21) Appl. No.: 12/564,933

(22) Filed: Sep. 23, 2009

(30) Foreign Application Priority Data
Sep. 26, 2008 (JP) 2008-248720

(51) Int. Cl. G11C 5/02; G11C 5/06

(52) U.S. Cl. 365/51; 365/72

(57) ABSTRACT

A semiconductor device is provided in which two adjacent cell lines extending in a word line direction are connected by one word line. Additionally, A semiconductor device comprising: word lines; bit lines which are disposed to cross the word lines; a plurality of cell lines extending in a word line direction; and a word line provided to share one cell line and the other cell line, of a pair of cell lines comprising two adjacent cell lines, wherein a distance between two adjacent cell lines in the pair of cell lines is smaller than a distance between two adjacent cell lines between one pair of cell lines and the other pair of cell lines.

### BACKGROUND OF THE INVENTION

1. Field of the Invention

The present invention relates to a semiconductor device.

Priority is claimed on Japanese Patent Application No. 2008-248720, filed Sep. 26, 2008, the content of which is incorporated herein by reference.

2. Description of Related Art

The chip size of semiconductor devices, particularly memory devices, has been reduced every year from the viewpoint of cost reduction. In DRAM (Dynamic Random Access Memory), a 4F²-cell structure has been proposed to satisfy this demand.

### SUMMARY

In one embodiment, there is provided a semiconductor device that includes at least: word lines; and bit lines which are disposed to cross the word lines, wherein two adjacent cell lines extending in a word line direction are connected by one word line.

Moreover, in another embodiment, there is provided a semiconductor device that includes at least: word lines; bit lines which are disposed to cross the word lines; cell lines extending in a word line direction; and word lines provided to share one cell line and the other cell line, of a pair of cell lines comprising two adjacent cell lines, wherein a distance between two adjacent cell lines in the pair of cell lines is smaller than a distance between two adjacent cell lines between one pair of cell lines and the other pair of cell lines.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plan view illustrating a cell transistor structure of a semiconductor device according to a first embodiment;

FIGS. 2A to 2D are views for explaining a layout of the semiconductor device according to the first embodiment, FIG. 2A is a plan view, FIG. 2B is a cross-sectional view taken along the line A-A′ shown in FIG. 2A, FIG. 2C is a cross-sectional view taken along the line B-B′ shown in FIG. 2A, and FIG. 2D is a cross-sectional view taken along the line C-C′ shown in FIG. 2A;

FIGS. 3A to 3G are schematic cross-sectional views for explaining a method of producing the semiconductor device according to the first embodiment;

FIGS. 4A and 4B are plan views for explaining the forming of a capacitor of a semiconductor device according to a second embodiment;

FIG. 5A is a plan view illustrating the forming of a first contact hole of the semiconductor device according to the second embodiment, and FIG. 5B is a cross-sectional view taken along the line D-D′ shown in FIG. 5A to explain the forming of a first bit line;

FIG. 6A is a plan view for explaining the forming of a second contact hole of the semiconductor device according to the second embodiment, and FIG. 6B is a cross-sectional view taken along the line E-E′ shown in FIG. 6A to explain the forming of a second bit line;

FIG. 7 is a plan view illustrating the known cell transistor structure in which 4F²-cell transistors are arranged in a word wiring direction; and

FIGS. 8A to 8C are views for explaining the known 4F² layout, FIG. 8A is a plan view, FIG. 8B is a cross-sectional view taken along the line F-F′ shown in FIG. 8A, and FIG. 8C is a cross-sectional view taken along the line G-G′ shown in FIG. 8A.

### DETAILED DESCRIPTION OF THE PREFERRED EMBODIMENTS

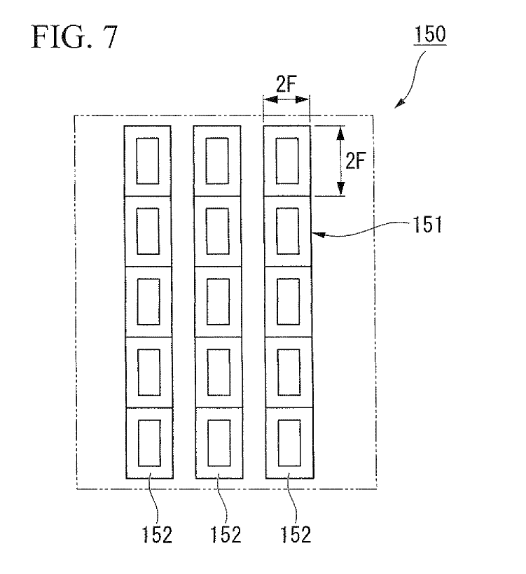

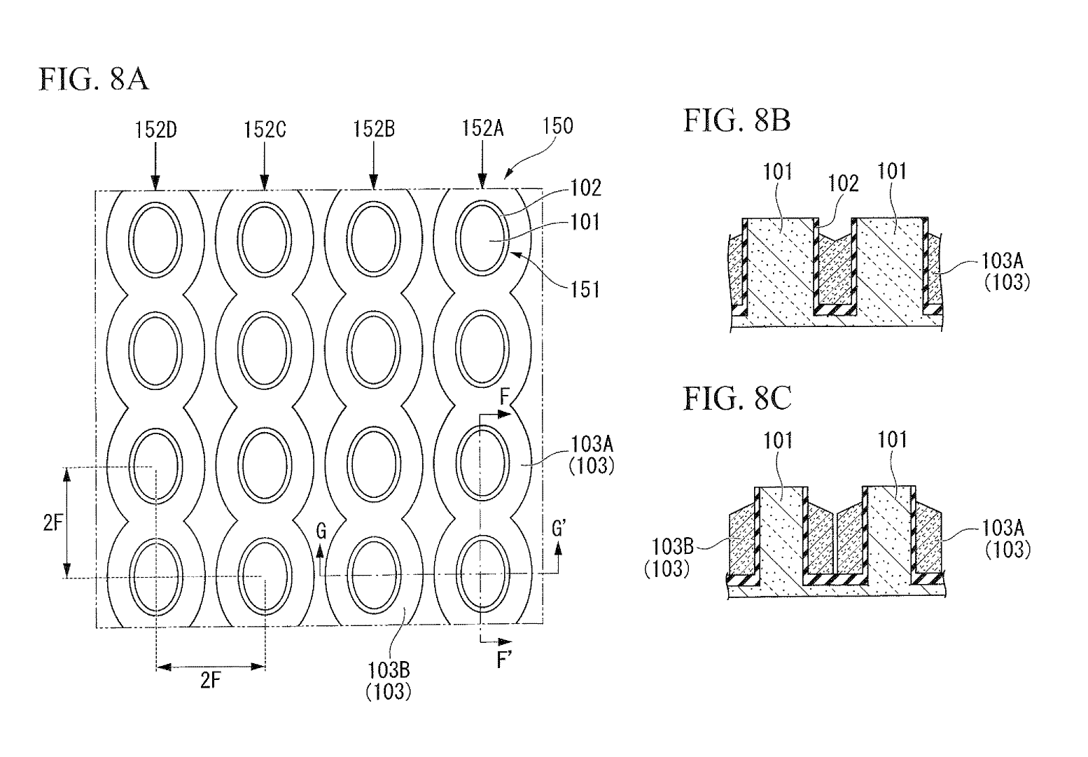

Before describing the present invention, the related art will be explained again in detail with reference to FIGS. 7, 8A, 8B and 8C, in order to facilitate the understanding of the present invention.

Several kinds of 4F²-cell structures have been proposed up to now. For example, FIG. 7 shows a schematic plan view of a cell transistor structure 150 having cell lines 152 where the known 4F²-cell transistors 151 are arranged in a word wiring direction. More specifically, as shown in FIGS. 8A to 8C, there is a cell transistor structure 151 in which an oxidized gate film 102 is formed in an outer periphery of a silicon post 101 having a lengthwise ratio and a breadthwise ratio different from each other and word lines 103A and 103B are magnetically and conformably formed by an etch-back process after forming a gate electrode 103. In Japanese Unexamined Patent Application, First Publication, No. 2004-96095, a layout is disclosed in which memory cells arranged in two lines are driven by one word line.

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, a semiconductor device according to the present invention will be described with reference to the drawings.

In the drawings used in the following description, specific parts may be enlarged for convenience to easily represent characteristics. Dimensions, ratios, and the like of constituent elements may not be equal to the actual ones. Materials, dimensions, and the like in the following description are examples, and the present invention is not limited thereto. The present invention may be appropriately modified within the scope of the invention.

### FIRST EMBODIMENT

In the embodiment, a case of applying the present invention to cell transistors arranged on a silicon substrate will be described by way of example.

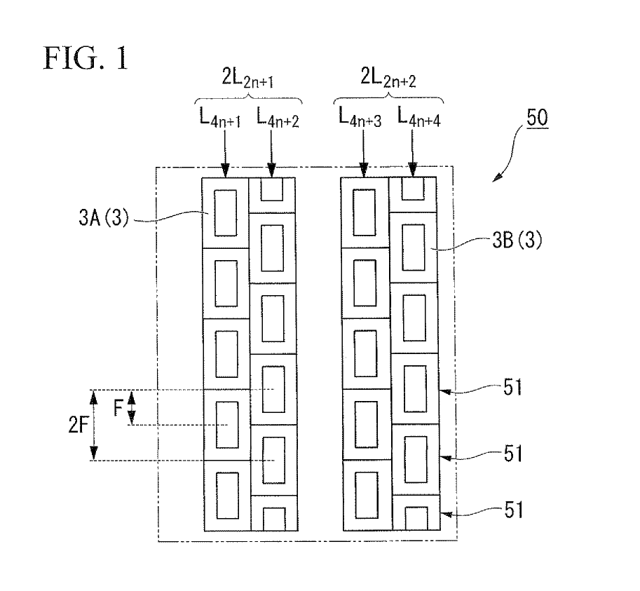

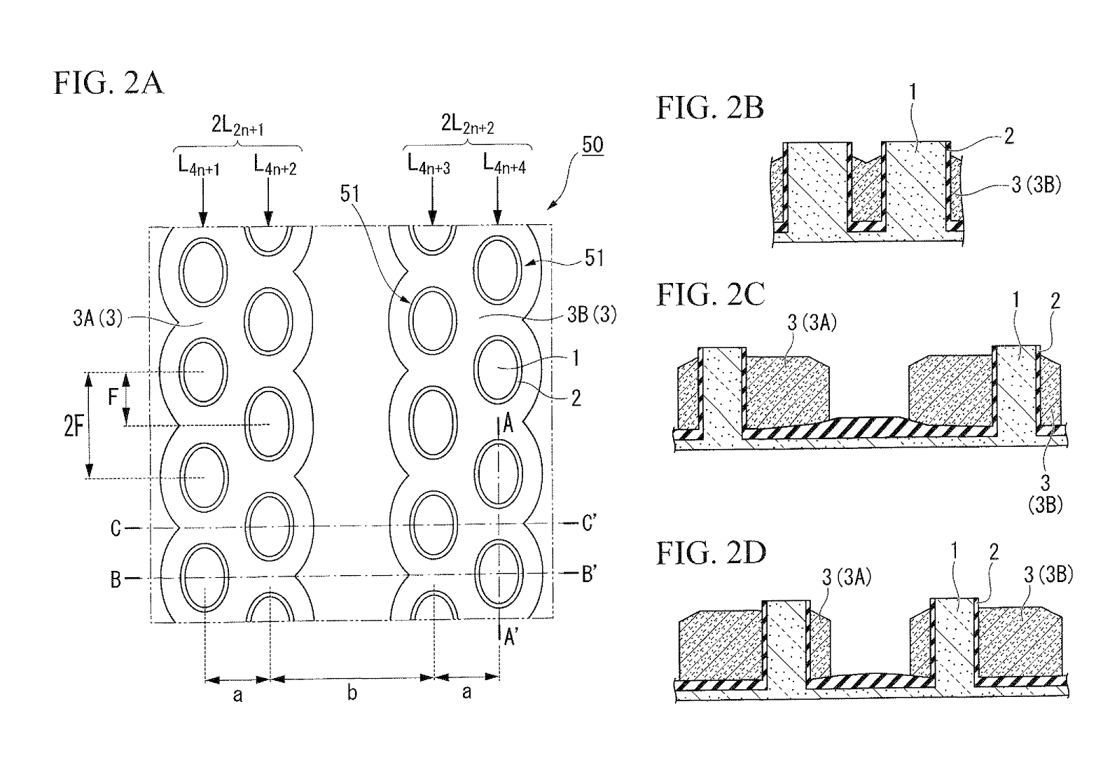

FIGS. 1 and 2A are plan views illustrating a semiconductor device on which cell transistors are arranged according to the first embodiment. As shown in FIGS. 1 and 2A, in a semiconductor device 50 according to the embodiment, cell lines (L₄ₙ₊₁ to L₄ₙ₊₄) extend in word lines 3A and 3B, and two adjacent cell lines (L₄ₙ₊₁ and L₄ₙ₊₂, or L₄ₙ₊₃ and L₄ₙ₊₄) are connected by one word line 3A or 3B. Here, “n” in the transcription of the cell lines indicates an integer.

More specifically, in the 4F² arrangement of the cell transistors 51 in the extending direction of the word lines 3A and 3B of the semiconductor device 50, the cell line L₄ₙ₊₂ (line₄ₙ₊₂) and the cell line L₄ₙ₊₃ (line₄ₙ₊₃) are shifted in the extending direction of the word line 3 by a width F of a minimum process dimension. The cell line L₄ₙ₊₂ and the cell line L₄ₙ₊₃ are shifted in the direction of the cell line L₄ₙ₊₁ (line₄ₙ₊₁) and the cell line L₄ₙ₊₄ (line₄ₙ₊₄) by the width F, thereby connecting the cell line L₄ₙ₊₁ and the cell line L₄ₙ₊₂ by the same word line 3A and connecting the cell line L₄ₙ₊₃ and the cell line L₄ₙ₊₄ by the same word line 3B.

As described above, one of the adjacent cell lines is shifted, thereby constituting a pair of cell lines 2L₂₊₁ and a pair of cell lines 2L₂₊₂ sharing the word lines 3A and 3B. In the pair of cell lines, the cell transistors 51 of two adjacent cell lines are disposed in a zigzag formation.

For example, longitudinal MOS transistors can be applied as the cell transistors 51 according to the embodiment, as shown in FIGS. 2A to 2D.

The cell transistor 51 at least includes a silicon post 1 and a gate electrode 3 coating a side face of the silicon post 1 through a gate insulating film 2. More specifically, the gate insulating film 2 is formed in a periphery of the silicon post 1 having a lengthwise ratio and a breadthwise ratio different from each other, and it is covered with the gate electrode 3. The cell transistor 51 has one impurity diffusion layer area (not shown) that becomes a source diffusion layer or a drain diffusion layer at an upper part of the silicon post 1, and has another impurity diffusion layer area (not shown) that becomes a source diffusion layer or a drain diffusion layer at a lower part of the silicon post 1.

As shown in FIG. 2A, the silicon posts 1 of the cell line L₄ₙ₊₂ and the cell line L₄ₙ₊₃ are shifted in the extending direction of the word lines 3A and 3B by the width F of the minimum process dimension. The cell line L₄ₙ₊₂ is shifted to the cell line L₄ₙ₊₁, and the cell line L₄ₙ₊₃ is shifted to the cell line L₄ₙ₊₄. Accordingly, a distance a between two adjacent cell lines (e.g., cell line L₄ₙ₊₁ and cell line L₄ₙ₊₂, cell line L₄ₙ₊₃ and cell line L₄ₙ₊₄) in one pair of cell lines is smaller than a distance b between two adjacent cell lines (e.g., cell line L₄ₙ₊₂ and cell line L₄ₙ₊₃) between the pair of cell lines and the pair of cell lines (2L₂ₙ₊₁ and 2L₂ₙ₊₂).

The silicon posts 1 having such a layout are applied as the cell transistors 51. Accordingly, in the semiconductor device 50, the gate electrodes 3 of the cell transistors 51 in the pair of cell lines (e.g., 2L₂ₙ₊₁, 2L₂ₙ₊₂) are integrated to constitute each of the word lines 3A and 3B.

As shown in FIGS. 2B to 2D, a thickness of the gate insulating film 2 between the pair of cell lines and the pair of cell lines (e.g., between 2L₂ₙ₊₁ and 2L₂ₙ₊₂) is larger than that within the pair of cell lines. That is, an area where the distance between the silicon posts 1 is large is thicker than an area where the distance is small.

Next, a method of producing the semiconductor device according to the embodiment will be described.

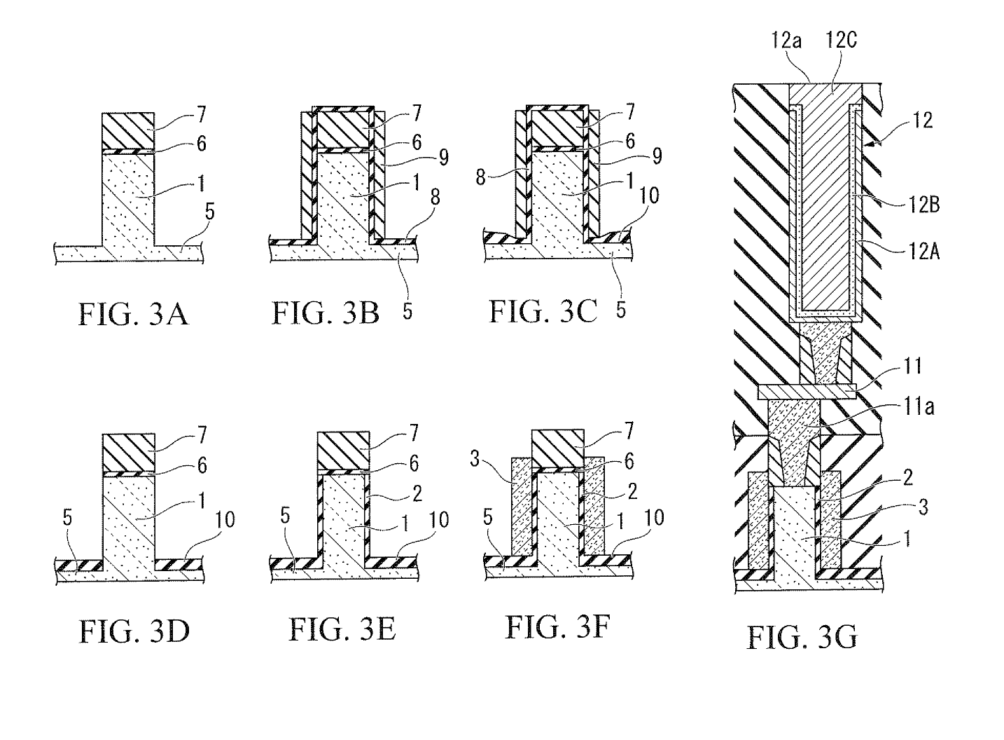

First, a silicon post 1 is formed. As shown in FIG. 3A, the silicon post 1 is formed by forming an oxide film 6 and a nitride film 7 on a semiconductor substrate 5. The nitride film 7 is patterned to have a layout of the silicon post 1 as shown in FIG. 2A. Subsequently, the silicon post 1 is formed by the patterned nitride film 7 as a mask.

Then, a thick oxide film is formed on the surface of the semiconductor substrate 5 at the lower part of the silicon post 1. First, an oxide film 8 and a nitride film are formed to cover the silicon post 1, the oxide film 6, and the nitride film 7 formed in FIG. 3A. Next, as shown in FIG. 3B, an etch-back process of the nitride film is performed until the oxide film 8 at the lower part of the silicon post 1 is exposed, and a side wall nitride film 9 is formed on the side wall of the silicon post 1.

Then, as shown in FIG. 3C, silicon under the exposed oxide film 8 is selectively thermal-oxidized, thereby forming a thick oxide film 10.

At that time, from the difference of the thermal-oxidized area, in FIGS. 2B to 2D, the thickness of the oxide film between the pair of cell lines and the pair of cell lines (e.g., between 2L₂ₙ₊₁ and 2L₂ₙ₊₂) becomes large as compared with that within the pair of cell lines. Accordingly, it is possible to increase an etch-back margin at the time of forming the gate electrode 3.

Next, as shown in FIG. 3D, the oxide film 8 covering the side wall nitride film 9 and the silicon post 1 is removed. Then, as shown in FIG. 3E, a gate insulating film 2 formed of an oxide film is formed on a side face of the silicon post 1.

Finally, a gate electrode 3 and a word line are formed. First, for example, poly silicon is formed on the whole side face of the silicon post 1 through the gate insulating film 2. Then, as shown in FIG. 3F, the gate electrode 3 is formed by the etch-back process. That is, at the same time of forming the gate electrode 3, one word line (word lines 3A and 3B shown in FIG. 2A) is magnetically and conformably formed with respect to two lines (e.g. cell line L₄ₙ₊₁ and cell line L₄ₙ₊₂, or cell line L₄ₙ₊₃ and cell line L₄ₙ₊₄ shown in FIG. 2A) of the silicon posts 1. In other words, the gate electrodes 3 of the cell transistors 51 of one pair of cell lines are integrated to form the word lines 3A and 3B. As described above, the semiconductor device 50 according to the embodiment is formed.

According to the semiconductor device 50 according to the embodiment, two adjacent cell lines (cell line L₄ₙ₊₁ and cell line L₄ₙ₊₂, or cell line L₄ₙ₊₃ and cell line L₄ₙ₊₄) are connected by one word line 3A or 3B, and thus it is possible to widen the areas of the word lines 3A and 3B. Accordingly, it is possible to increase the distance between the word lines 3A and 3B. Therefore, it is possible to reduce resistance of the word lines and it is possible to reduce capacitance of the word lines.

When the resistance is estimated by the schematic diagram of the known layout as shown in FIG. 7 and the schematic diagram of the layout of the present invention as shown in FIG. 1, the area is doubled, resistance per unit length is reduced by ½, and the number of bits included in the unit length is doubled. Accordingly, resistance per 1 bit can be estimated as ¼. The distance from the adjacent word line is doubled, and thus it is possible to reduce the capacitance of the word line by ½.

### SECOND EMBODIMENT

Next, a second embodiment of the invention will be described.

In the embodiment, for example, a case of applying the invention to a layout method of memory cells arranged on a silicon substrate will be described by way of example.

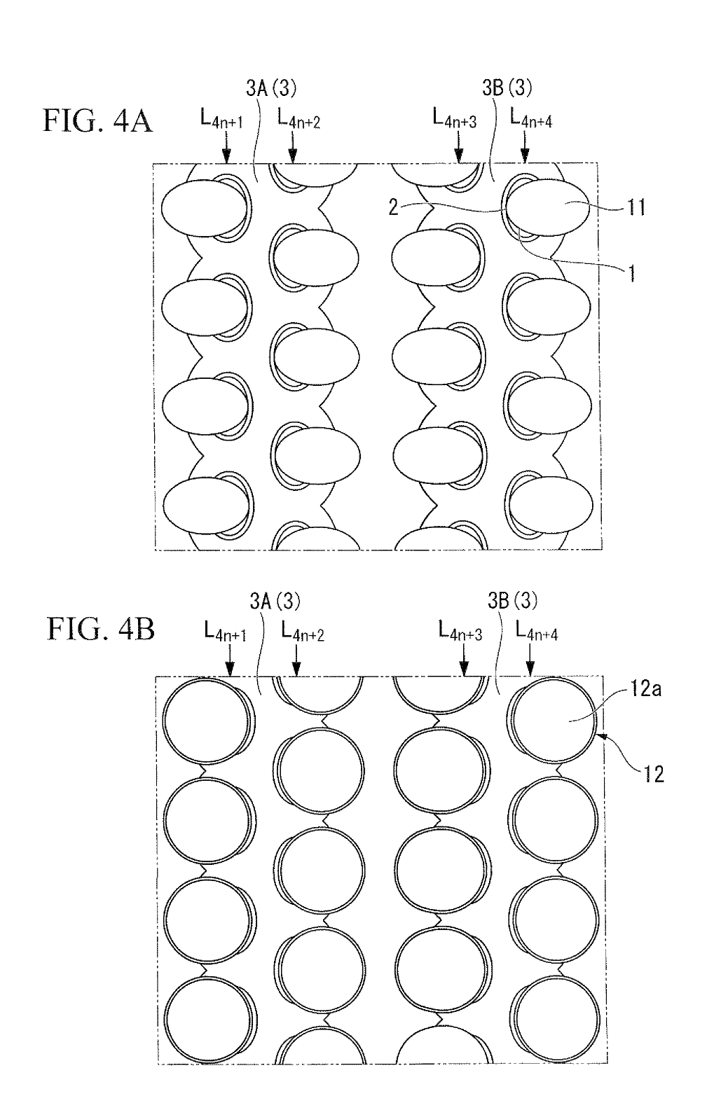

As shown in FIGS. 3G, 4A, and 4B, in a semiconductor device according to the embodiment, schematically, capacitors are formed on the cell transistors 51 constituting the semiconductor device 50 according to the first embodiment, and bit lines connected onto the capacitors are formed so that distances from the surface of the semiconductor substrate are different (i.e., layers are different) from one another for each cell line.

Specifically, as shown in FIG. 3F, a part of the mask nitride film 7 is removed, and a cell contact 11a is formed. As shown in FIGS. 3F and 4A, a capacitance contact pad 11 is formed on the cell contact 11a. In this case, the central position of the capacitance contact pad 11 of each cell line slightly deviates from the central position of the upper face of the silicon post 1 in the plan view. That is, as shown in FIG. 4A, the silicon posts 1 are formed to deviate toward the opposite side from the silicon posts 1 of the adjacent cell, line in the same pair of cell lines.

As shown in FIG. 4B, a capacitor 12 including an upper electrode 12A, a dielectric substance 12B, and a lower electrode 12C is formed on the capacitance contact pad 11. In this case, an upper face 12a of each capacitor 12 is provided so that the capacitor 12 of any cell line is at the same height (i.e. the same layer) from the surface of the semiconductor substrate.

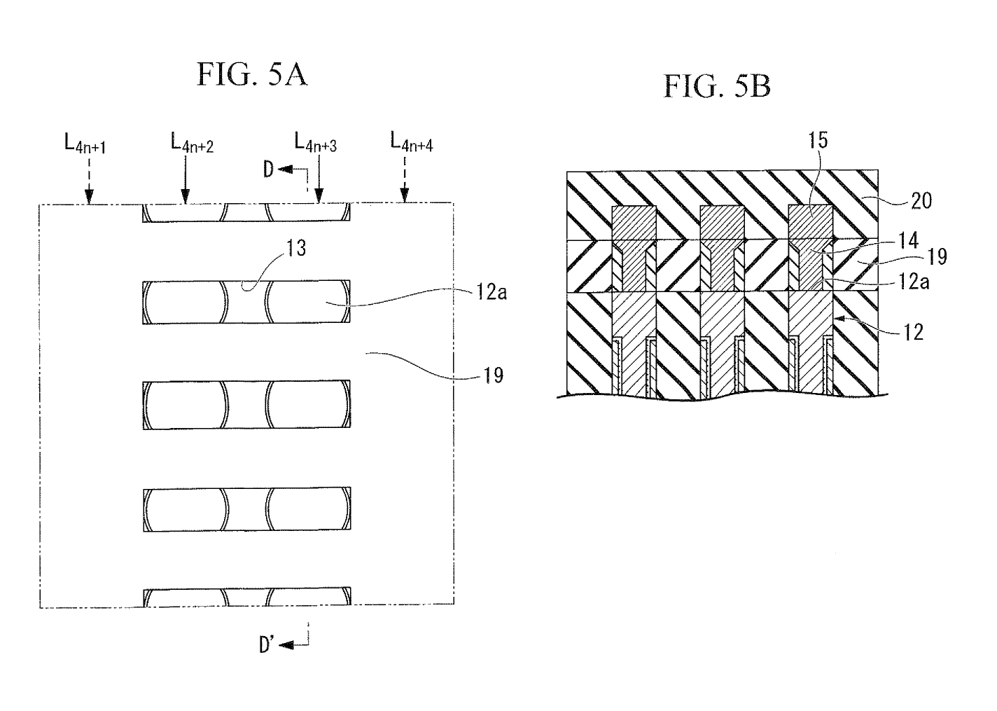

Next, an interlayer insulating film 19 is formed to cover all the cell lines. As shown in FIG. 5A, a part of the interlayer insulating film 19 on the adjacent cell lines (L₄ₙ₊₂ and L₄ₙ₊₃) between the adjacent pairs (e.g., 2L₂ₙ₊₁ and 2L₂ₙ₊₂) of cell lines is opened to form a first contact hole 13 for the upper face 12a of the capacitor 12. Then, as shown in FIG. 5B, a first bit contact 14 and a first bit line 15 are formed.

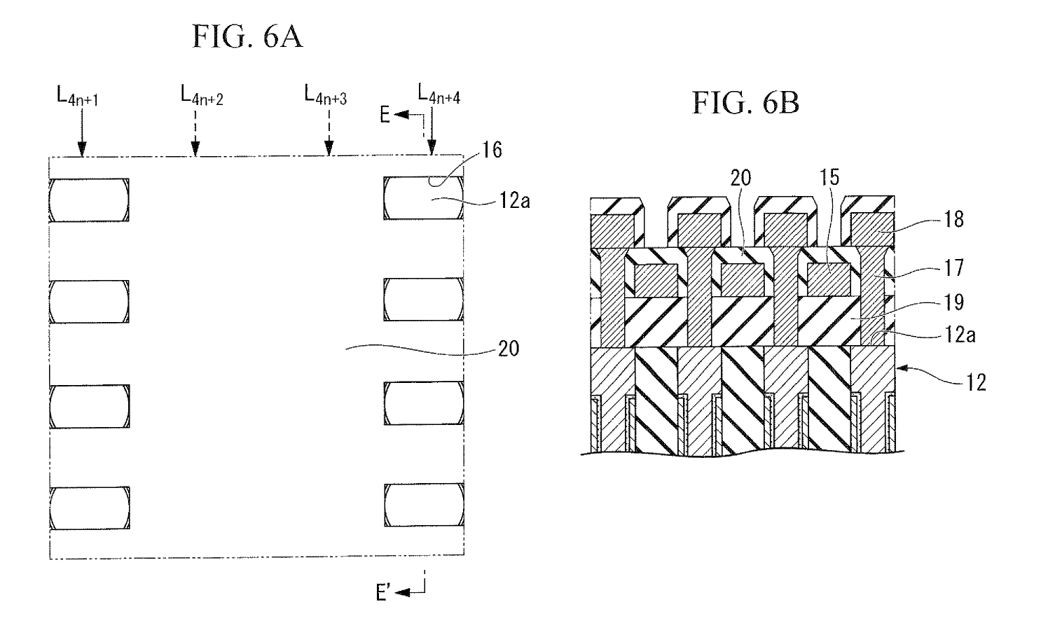

Next, as shown in FIG. 5B, an interlayer insulating film 20 is formed so as to cover the first bit line 15. In this case, as shown in FIG. 6A, the cell line L₄ₙ₊₁ and the cell line L₄ₙ₊₄ are adjacent to a cell line L₄₍ₙ₋₁₎₊₄ and a cell line L₄₍ₙ₊₁₎₊₁ (not shown), respectively. Accordingly, in the same manner as the first contact hole 13, part of the interlayer insulating film 20 on the adjacent cell lines (e.g., L₄₍ₙ₋₁₎₊₄ and L₄ₙ₊₁) between the adjacent pairs (e.g., 2L₂₍ₙ₋₁₎₊₂ and 2L₂ₙ₊₁) of cell lines is opened to form a second contact hole 16 for the upper face 12a of the capacitor 12, Then, as shown in FIG. 6B, a second bit contact 17 and a second bit line 18 are formed.

Accordingly, as shown in FIG. 6B, the semiconductor device is formed so that the second bit line 18 of one cell line (e.g., L₄ₙ₊₁) of the pair of cell lines and the first bit line 15 of the other cell line (e.g., L₄ₙ₊₂) are provided at layers having different heights from the capacitor 12 of the pair of cell lines.

According to the semiconductor device according to the second embodiment, in the first embodiment, as shown in FIG. 2A, the adjacent cell lines (e.g., L₄₍ₙ₋₁₎₊₄ and L₄ₙ₊₁) between the adjacent pairs (e.g., 2L₂₍ₙ₋₁₎₊₂ and 2L₂ₙ₊₁) of cell lines are shifted by the same width F, and thus commonality of contact for the adjacent cell lines (e.g., L4₍ₙ₋₁₎₊₄ and L₄ₙ₊₁) between the pairs (e.g., 2L₂₍ₙ₋₁₎₊₂ and 2L₂ₙ₊₁) of cell lines with respect to the capacitance upper electrode 12 becomes possible.

In the first embodiment and the second embodiment, the adjacent bit lines are formed of layers.

According to the semiconductor device of the present invention, two adjacent cell lines are connected by one word line. Accordingly, it is possible to widen the area of the word line, and to increase the distance between the word lines. Therefore, it is possible to reduce the resistance of the word lines and to reduce the capacitance between the word lines.

It is apparent that the present invention is not limited to the above embodiments, but may be modified and changed without departing from the scope and spirit of the invention.

What is claimed is:

1. A semiconductor device comprising:
word lines; and
bit lines which are disposed to cross the word lines,
wherein two adjacent cell lines extending in a word line direction are connected by one word line.

2. The semiconductor device according to claim 1, wherein two adjacent cell lines are set to a pair of cell lines, a distance between the two adjacent cell lines is smaller than a distance between the pair of adjacent cell lines.

3. The semiconductor device according to claim 1, wherein cells in two adjacent cell lines are disposed in a zigzag formation in a word direction.

4. The semiconductor device according to claim 1, wherein two adjacent cell lines are set to a pair of cell lines, a distance between the two adjacent cell lines is smaller than a distance between the pair of adjacent cell lines, and cells in two adjacent cell lines are disposed in a word direction.

5. The semiconductor device according to claim 1, wherein two adjacent cell lines are set to a pair of cell lines, a distance between the two adjacent cell lines is smaller than a distance between the pair of adjacent cell lines, and cells in two adjacent cell lines are disposed in a zigzag formation in a word direction.

6. The semiconductor device according to claim 1, wherein the adjacent bit lines are formed of layers.

7. The semiconductor device according to claim 1, wherein in the arrangement of cell transistors in the word line direction, the line₄ₙ₊₁ and the line₄ₙ₊₂ are connected to the same word line and the line₄ₙ₊₃ and the line₄ₙ₊₄ are connected to the same word line.

8. The semiconductor device according to claim 1, wherein in the arrangement of the cell transistors in the word line direction, a line₄ₙ₊₂ and a line₄ₙ₊₃ are shifted by a width of a minimum process dimension, and a line₄ₙ₊₂ and a line₄ₙ₊₃ are shifted in a direction of a line₄ₙ₊₁ and a line₄ₙ₊₄, thereby connecting the line₄ₙ₊₁ and the line₄ₙ₊₂ to the same word line and connecting the line₄ₙ₊₃ and the line₄ₙ₊₄ to the same word line.

9. The semiconductor device according to claim 5, wherein a thickness of the gate insulating film between the pair of cell lines and the pair of cell lines is larger than that within the pair of cell lines.

10. A semiconductor device comprising:
word lines;
bit lines which are disposed to cross the word lines;
cell lines extending in a word line direction; and
word lines provided to share one cell line and the other cell line, of a pair of cell lines comprising two adjacent cell lines,
wherein a distance between two adjacent cell lines in the pair of cell lines is smaller than a distance between two adjacent cell lines between one pair of cell lines and the other pair of cell lines.

11. The semiconductor device according to claim 10, wherein the cell lines are provided with cell transistors are arranged in the word line direction, and
the cell transistors of the pair of cell lines are arranged so that the cell transistors of one cell line and the cell transistors of the other cell line deviate from each other in the word line direction.

12. The semiconductor device according to claim 10, wherein the cell lines are provided with cell transistors are arranged in the word line direction, and
the cell transistors of the pair of cell lines are arranged in a zigzag formation so that the cell transistors of one cell line and the cell transistors of the other cell line deviate from each other in the word line direction.

13. The semiconductor device according to claim 12, wherein the cell transistors of one cell line and the cell transistors of the other cell line deviate from each other in the word line direction by a width of a minimum process dimension of the cell transistors.

14. The semiconductor device according to claim 10, wherein a bit line of one cell line and a bit line of the other cell line, of the pair of cell lines are provided in layers having different heights from the pair of cell lines.

15. The semiconductor device according to claim 11, wherein the cell transistors comprise a semiconductor post and a gate electrode coating a side face of the semiconductor post through a gate insulating film.

16. The semiconductor device according to claim 15, wherein the semiconductor post is silicon post.

17. The semiconductor device according to claim 16, wherein the word lines are formed by integrating the gate electrodes of the cell transistors of the pair of cell lines.

18. The semiconductor device according to claim 12, wherein a thickness of the gate insulating film between the pair of cell lines and the pair of cell lines is larger than that within the pair of cell lines.
